(19) United States
(12) Patent Application Publication
(10) Pub. No.: US 2022/0246582 A1
(43) Pub. Date: Aug. 4, 2022

(54) SEMICONDUCTOR PACKAGE

(71) Applicant: Samsung Electronics Co., Ltd., Suwon-si (KR)

(72) Inventors: GEOL NAM, Seoul (KR); GUNHO CHANG, Yongin-si (KR); CHUL-YONG JANG, Suwon-si (KR); Dongjoo CHOI, Seoul (KR)

(21) Appl. No.: 17/495,612

(22) Filed: Oct. 6, 2021

(30) Foreign Application Priority Data
Jan. 29, 2021 (KR) 10-2021-0013548

(51) Int. Cl. H01L 25/065; H01L 25/18

(52) U.S. Cl. CPC H01L 25/0657; H01L 25/18; H01L 25/0652; H01L 23/3185; H01L 2225/06513; H01L 2225/06517; H01L 2225/06544

(57) ABSTRACT

Disclosed is a semiconductor package comprising a lower semiconductor chip and upper semiconductor chips vertically stacked on a top surface of the lower semiconductor chip. The upper semiconductor chips include first upper semiconductor chips and a second upper semiconductor chip. The first upper semiconductor chips are between the lower semiconductor chip and the second upper semiconductor chip. A thickness of each of the first upper semiconductor chips is 0.4 to 0.95 times that of the lower semiconductor chip. A thickness of the second upper semiconductor chip is the same as or greater than that of the first upper semiconductor chip. A total number of the first and second upper semiconductor chips is 4n, wherein n is a natural number equal to or greater than three.

### CROSS-REFERENCE TO RELATED APPLICATION

This U.S. nonprovisional application claims priority under 35 U.S.C § 119 to Korean Patent Application No. 10-2021-0013548 filed on Jan. 29, 2021 in the Korean Intellectual Property Office, the disclosure of which is hereby incorporated by reference in its entirety.

### BACKGROUND

The present inventive concepts relate to a semiconductor package, and more particularly, to a semiconductor package including stacked chips.

A semiconductor package is provided to implement an integrated circuit chip to qualify for use in electronic products. Typically, a semiconductor package is configured such that a semiconductor chip is mounted on a printed circuit board and bonding wires or bumps are used to electrically connect the semiconductor chip to the printed circuit board. With the development of electronic industry, a semiconductor package may be required to have high-capacity characteristics. According to a trend toward compactness of electronic products, it is required that a semiconductor package become compact-sized.

### SUMMARY

Some example embodiments of the present inventive concepts provide a compact semiconductor package with high capacity.

According to some example embodiments of the present inventive concepts, a semiconductor package may comprise: a lower semiconductor chip; and a plurality of upper semiconductor chips that are vertically stacked on a top surface of the lower semiconductor chip. The upper semiconductor chips may include a plurality of first upper semiconductor chips and a second upper semiconductor chip. The first upper semiconductor chips may be between the lower semiconductor chip and the second upper semiconductor chip. A thickness of each of the first upper semiconductor chips may be about 0.4 times to about 0.95 times a thickness of the lower semiconductor chip. A thickness of the second upper semiconductor chip may be the same as or greater than the thickness of each of the first upper semiconductor chips. A total number of the first upper semiconductor chips and the second upper semiconductor chip may be 4n, wherein n may be a natural number equal to or greater than three.

According to some example embodiments of the present inventive concepts, a semiconductor package may comprise: a first semiconductor chip that includes a first semiconductor substrate, a first circuit layer, and a first through structure; and a plurality of second semiconductor chips that are vertically stacked on a top surface of the first semiconductor chip. Each of the second semiconductor chips may include a second semiconductor substrate, a second circuit layer, and a second through structure. A thickness of each of the second semiconductor chips may be about 0.4 times to about 0.95 times a thickness of the first semiconductor chip. A second ratio of a thickness of the second semiconductor substrate to a thickness of the second circuit layer may be less than a first ratio of a thickness of the first semiconductor substrate to a thickness of the first circuit layer.

According to some example embodiments of the present inventive concepts, a semiconductor package may comprise: a first semiconductor chip; a plurality of solder terminals on a bottom surface of the first semiconductor chip; a plurality of second semiconductor chips that are vertically stacked on a top surface of the first semiconductor chip; a third semiconductor chip on the second semiconductor chips; and a molding layer on the top surface of the first semiconductor chip. The molding layer may cover sidewalls of the second semiconductor chips and a sidewall of the third semiconductor chip. The first semiconductor chip may include: a first semiconductor substrate; a plurality of first integrated circuits on one surface of the first semiconductor substrate; a first circuit layer on the one surface of the first semiconductor substrate, the first circuit layer including a first dielectric layer and a first wiring structure; and a first through structure formed in the first semiconductor substrate and electrically connected to the first integrated circuits. Each of the second semiconductor chips may include: a second semiconductor substrate; a plurality of second integrated circuits on one surface of the second semiconductor substrate; a second circuit layer on the one surface of the second semiconductor substrate, the second circuit layer including a second dielectric layer and a second wiring structure; and a second through structure formed in the second semiconductor substrate and electrically connected to the second integrated circuits. The third semiconductor chip may include: a third semiconductor substrate; a plurality of third integrated circuits on one surface of the third semiconductor substrate; and a third circuit layer on the one surface of the third semiconductor substrate. The third circuit layer may include a third dielectric layer and a third wiring structure. The third semiconductor chip may not include a through structure. A ratio of a thickness of the first semiconductor substrate to a thickness of the first circuit layer may be in a range of about 1.7 to about 10. A ratio of a thickness of the second semiconductor substrate to a thickness of the second circuit layer may be in a range of about 0.5 to about 1.5. A thickness of each of the second semiconductor chips may be about 0.4 times to about 0.95 times a thickness of the first semiconductor chip. A thickness of the third semiconductor chip may be greater than the thickness of each of the second semiconductor chips. A total number of the second semiconductor chips and the third semiconductor chip may be 4n, wherein n may be a natural number equal to or greater than three.

### BRIEF DESCRIPTION OF THE DRAWINGS

FIG. 1A illustrates a cross-sectional view showing a semiconductor package according to some example embodiments.

FIG. 1B illustrates an enlarged view showing section I of FIG. 1A.

FIG. 1C illustrates an enlarged view showing section II of FIG. 1A.

FIG. 1D illustrates an enlarged view showing section III of FIG. 1A.

FIG. 2 illustrates a cross-sectional view showing a semiconductor package according to some example embodiments.

FIG. 3 illustrates a cross-sectional view showing a semiconductor package according to some example embodiments.

FIG. 4A illustrates a plan view showing a semiconductor package according to some example embodiments.

FIG. 4B illustrates a cross-sectional view taken along line IV-IV′ of FIG. 4A.

### DETAILED DESCRIPTION OF EMBODIMENTS

In this description, like reference numerals may indicate like components. The following will now describe semiconductor packages according to the present inventive concepts.

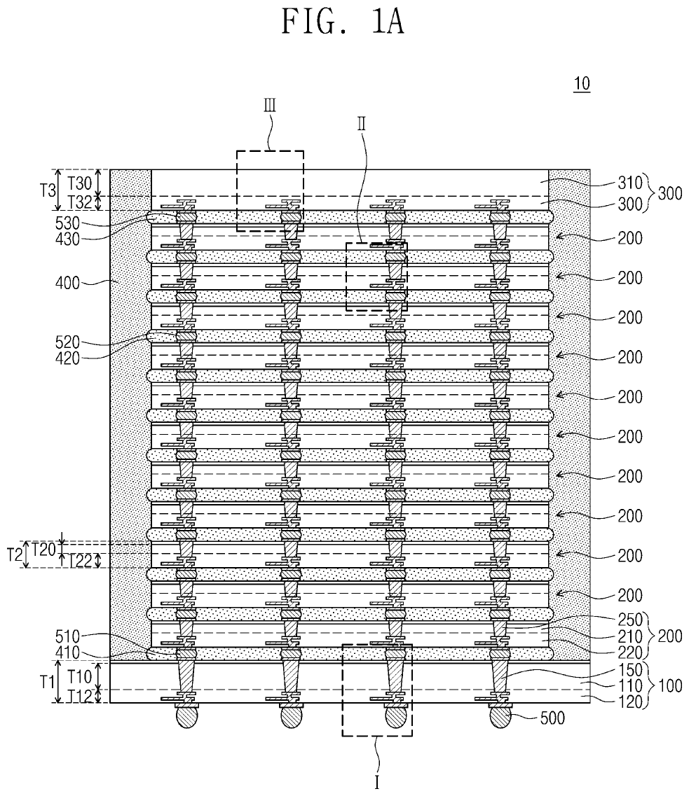

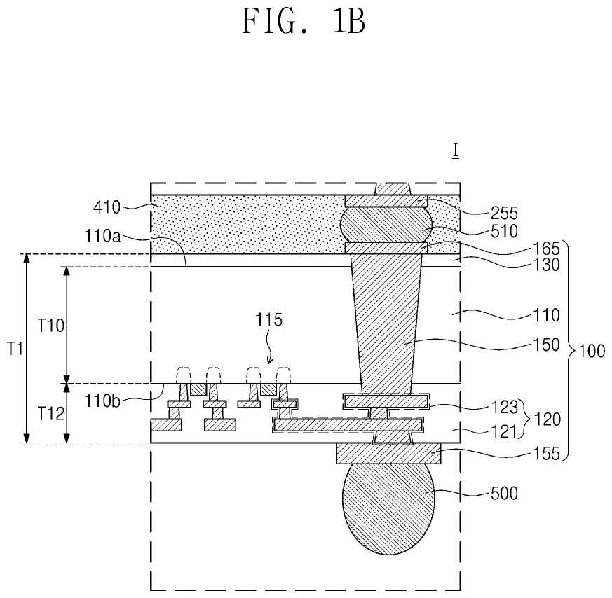

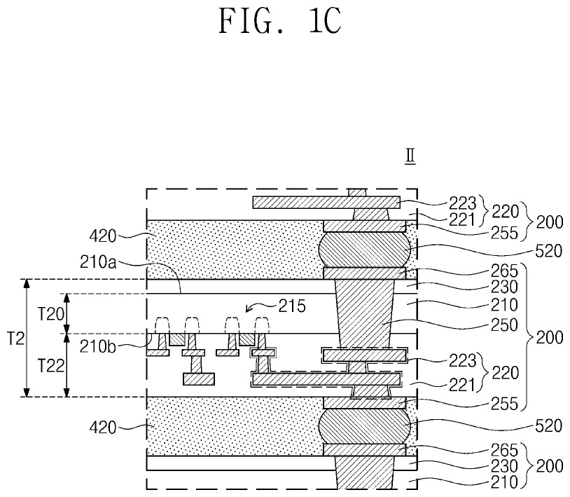

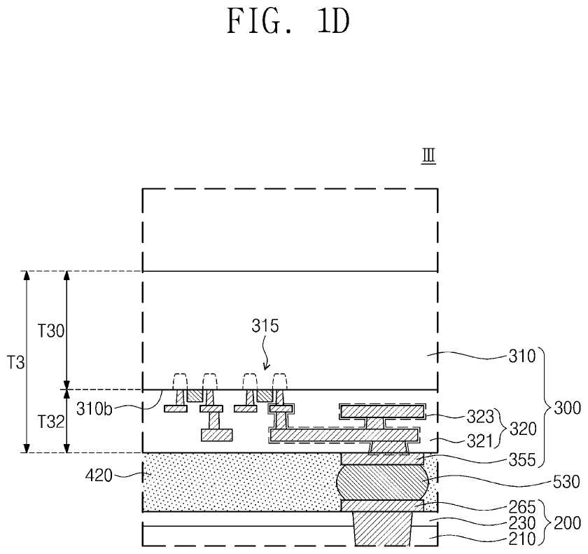

FIG. 1A illustrates a cross-sectional view showing a semiconductor package according to some example embodiments. FIG. 1B illustrates an enlarged view showing section I of FIG. 1A. FIG. 1C illustrates an enlarged view showing section II of FIG. 1A. FIG. 1D illustrates an enlarged view showing section III of FIG. 1A.

Referring to FIGS. 1A, 1B, 1C, and 1D, a semiconductor package may be a chip stack package 10. The chip stack package 10 may include a first semiconductor chip 100, second semiconductor chips 200, a third semiconductor chip 300, a solder terminal 500, and a molding layer 400.

The first semiconductor chip 100 may be a lower semiconductor chip. The first semiconductor chip 100 may include or may be a logic chip, a controller chip, or a buffer chip. For example, the first semiconductor chip 100 may control the second semiconductor chips 200 and the third semiconductor chip 300. The first semiconductor chip 100 may have a first thickness T1. The first thickness T1 may range from about 30 μm to about 60 μm. When the first thickness T1 is greater than about 60 μm, the chip stack package 10 may be difficult to become compact-sized. When the first thickness T1 is less than about 30 μm, the first semiconductor chip 100 may be damaged due to weight of the second semiconductor chips 200.

An upper semiconductor chip may be disposed on the lower semiconductor chip. The upper semiconductor chip may include or may be one of the second semiconductor chips 200 and the third semiconductor chip 300. For example, the chip stack package 10 may include a plurality of upper semiconductor chips. The second semiconductor chips 200 may be first upper semiconductor chips, and the third semiconductor chip 300 may be a second upper semiconductor chip.

A plurality of second semiconductor chips 200 may be provided on the first semiconductor chip 100. The second semiconductor chips 200 may be vertically stacked on a top surface of the first semiconductor chip 100. Unless otherwise specially limited in this description, the term “vertically” may mean “substantially perpendicular to the top surface of the first semiconductor chip 100.”

The second semiconductor chips 200 may be of a different type from the first semiconductor chip 100. For example, the second semiconductor chips 200 may be memory chips such as dynamic random access memory (DRAM) chips. The memory chips may include high bandwidth memory (HBM) chips. The second semiconductor chips 200 may have the same storage capacity, but the present inventive concepts are not limited thereto.

The second semiconductor chips 200 may have the same size, but the present inventive concepts are not limited thereto. For example, the second semiconductor chips 200 may have substantially the same width. For example, the second semiconductor chips 200 may have sidewalls that are vertically aligned with each other. For example, the sidewalls of the second semiconductor chips 200 may be vertically aligned with each other. The widths of the second semiconductor chips 200 may be less than that of the first semiconductor chip 100. A width of a certain component may be measured in a direction parallel to the top surface of the first semiconductor chip 100. The phrase “certain components are the same in terms of thickness, size, level, and/or width” may include an allowable tolerance possibly occurring during fabrication process.

For example, terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The second semiconductor chips 200 may have substantially the same thickness. For example, each of the second semiconductor chips 200 may have a second thickness T2. The second thickness T2 may be less than the first thickness T1. The second thickness T2 may be about 0.4 times to about 0.95 times the first thickness T1. For example, the second thickness T2 may be about 0.4 times to about 0.9 times the first thickness T1. When the second thickness T2 is less than about 0.4 times the first thickness T1, the second semiconductor chips 200 may be damaged or difficult to handle. The damage to the second semiconductor chips 200 may occur during fabrication or delivery of the second semiconductor chips 200. The damage to the second semiconductor chips 200 may include, for example, the generation of cracks. When the second thickness T2 is greater than about 0.95 times the first thickness T1, the chip stack package 10 may be difficult to become compact-sized. According to some example embodiments, because the second thickness T2 is about 0.4 times to about 0.95 times the first thickness T1, the second semiconductor chips 200 may be prevented from being damaged, and the chip stack package 10 may become small in size.

The second thickness T2 may range from about 25 μm to about 50 μm. When the first thickness T1 is greater than about 50 μm, the chip stack package 10 may be difficult to become compact-sized. When the second thickness T2 is less than about 25 μm, the second semiconductor chips 200 may be easily damaged and may be difficult to handle. According to some example embodiments, because the second thickness T2 ranges from about 25 μm to about 50 μm, the second semiconductor chips 200 may be prevented from being damaged, and the chip stack package 10 may become small in size.

The third semiconductor chip 300 may be disposed on an uppermost one of the second semiconductor chips 200. For example, the second semiconductor chips 200 may be interposed between the first semiconductor chip 100 and the third semiconductor chip 300.

The third semiconductor chip 300 may be of a different type from the first semiconductor chip 100. The third semiconductor chip 300 may be of the same type as the second semiconductor chips 200. For example, the third semiconductor chip 300 may be a memory chip such as a dynamic random access memory (DRAM) chip. The third semiconductor chip 300 may be a high bandwidth memory chip. The third semiconductor chip 300 may have the same storage capacity as that of the second semiconductor chips 200, but the present inventive concepts are not limited thereto.

The third semiconductor chip 300 may have a width substantially the same as those of the second semiconductor chips 200. The third semiconductor chip 300 may have sidewalls vertically aligned with those of the second semiconductor chips 200. For example, the third semiconductor chip 300 may have four sidewalls, and each of the four sidewalls of the third semiconductor chip 300 and corresponding sidewalls of the second semiconductor chips 200 may be coplanar. The widths of the third semiconductor chip 300 may be less than that of the first semiconductor chip 100.

The third semiconductor chip 300 may have a third thickness T3. The third thickness T3 may be the same as or greater than the second thickness T2. Thus, the third semiconductor chip 300 may be prevented from damage due to external impact.

A sum of the number of the second semiconductor chips 200 and the number of the third semiconductor chip 300 may be expressed by 4n, wherein n is a natural number equal to or greater than 3 For example, the sum of the numbers of the second and third semiconductor chips 200 and 300 may be twelve. Differently from that shown in FIG. 1A, the sum of the numbers of the second and third semiconductor chips 200 and 300 may be 16, 20, 24, or variously changed.

An electrical connection inspection may be performed on the second semiconductor chips 200 and the third semiconductor chip 300 in a process where the second and third semiconductor chips 200 and 300 are stacked. In this case, the electrical connection inspection may be performed by using an inspection apparatus that satisfies standard specifications. The standard specifications may be JEDEC (joint electron device engineering council) standards. The inspection apparatus may be used to inspect four semiconductor chips per electrical connection inspection. According to some embodiments, because the sum of the numbers of the second and third semiconductor chips 200 and 300 satisfies the expression 4n, e.g., multiples of 4, it may be beneficial to effectively perform the stack and inspection processes of the second and third semiconductor chips 200 and 300.

The third semiconductor chip 300 may be an uppermost semiconductor chip, and the chip stack package 10 may include a single third semiconductor chip 300. Therefore, the total number of the second semiconductor chips may be expressed by 4n−1, wherein n is a natural number equal to or greater than 3.

The more number of stacked second semiconductor chips 200, the larger storage capacity of the chip stack package 10. Because n is a natural number equal to or greater than 3, the chip stack package 10 may have increased storage capacity.

In general, the higher number of stacked second semiconductor chips 200, the larger thickness of the chip stack package 10. According to some embodiments, because the second thickness T2 of each second semiconductor chip 200 is about 0.4 times to about 0.95 times the first thickness T1, the chip stack package 10 may become compact-sized even in the case of an increase in the number of stacked second semiconductor chips 200. For example, a condition may be satisfied where a range between about 500 μm and about 1,000 μm is given as an interval/distance between a top surface of the third semiconductor chip 300 and a bottom surface of the first semiconductor chip 100. For example, a range between about 500 μm and about 850 μm may be given as the interval/distance between the top surface of the third semiconductor chip 300 and the bottom surface of the first semiconductor chip 100. Therefore, the chip stack package 10 may have characteristics of high capacity and compactness.

The following will describe in detail configurations of the first and second semiconductor chips 100 and 200.

Referring to FIGS. 1A and 1B, the first semiconductor chip 100 may include a first semiconductor substrate 110, first integrated circuits 115, a first circuit layer 120, a first chip pad 155, and a first through structure 150. The first semiconductor substrate 110 may include a semiconductor material, such as silicon, germanium, or silicon-germanium. The first semiconductor substrate 110 may have a crystalline structure. The first integrated circuits 115 may be provided on one surface of the first semiconductor substrate 110. The one surface may be a bottom surface 110b of the first semiconductor substrate 110. The first integrated circuits 115 may include, for example, transistors. The first integrated circuits 115 may include logic circuits.

The first circuit layer 120 may be provided on the bottom surface 110b of the first semiconductor substrate 110. The first circuit layer 120 may include a first dielectric layer 121 and first wiring structures 123. The first dielectric layer 121 may be provided on the bottom surface 110b of the first semiconductor substrate 110 and may cover the first integrated circuits 115. The first dielectric layer 121 may include or be formed of a silicon-based dielectric material. The silicon-based dielectric material may include, for example, one or more of silicon oxide, silicon nitride, silicon oxynitride, and tetraethyl orthosilicate (TEOS). The first circuit layer 120 may have a thickness T12 that corresponds to an interval/distance between top and bottom surfaces of the first dielectric layer 121. The first dielectric layer 121 may include or be formed of a plurality of stacked layers. When the first dielectric layer 121 includes a plurality of layers, the thickness T12 of the first circuit layer 120 may correspond to an interval/distance between a bottom surface of a lowermost layer of the first dielectric layer 121 and a top surface of an uppermost layer of the first dielectric layer 121.

The first wiring structures 123 may be provided in the first dielectric layer 121. The first wiring structures 123 may be electrically connected to the first integrated circuits 115. Each of the first wiring structures 123 may include a first line part and a first via part that are electrically connected to each other. For example, the first line part may be a conductor pattern extending horizontally, and the first via part may be a conductor pattern extending vertically. The first via part may have a width less than that of the first line part. In this description, the phrase “electrically connected/coupled” may include a direct connection/coupling or an indirect connection/coupling through other conductive component(s). The phrase “electrically connected to a semiconductor chip” may mean that “electrically connected to integrated circuits of the semiconductor chip.”

As used herein, components described as being “electrically connected” are configured such that an electrical signal can be transferred from one component to the other (although such electrical signal may be attenuated in strength as it transferred and may be selectively transferred).

A plurality of first chip pads 155 may be exposed on the bottom surface of the first semiconductor chip 100. For example, the first chip pads 155 may be disposed on a bottom surface of the first circuit layer 120. The first chip pads 155 may be electrically connected through the first wiring structures 123 to the first integrated circuits 115. The phrase “a component is coupled to a chip pad” may mean that the component is coupled to a semiconductor chip. The first chip pads 155 may include metal, such as aluminum.

The first through structure 150 may be provided in and may penetrate the first semiconductor substrate 110. The first through structure 150 may further penetrate at least a portion of the first circuit layer 120. The first semiconductor chip 100 may include a plurality of first through structures 150. The plurality of first through structures 150 may be laterally spaced apart from each other. The first through structures 150 may be electrically connected through the first wiring structures 123 to the first chip pads 155 and/or the first integrated circuits 115. The first through structures 150 may include or be formed of a conductive material, such as copper, titanium, tungsten, or any alloy thereof.

The first semiconductor chip 100 may include a first backside dielectric layer 130 and first bonding pads 165. The first backside dielectric layer 130 may be disposed on a top surface 110a of the first semiconductor substrate 110. The top surface 110a may be opposite to the bottom surface 110b of the first semiconductor substrate 110. The first backside dielectric layer 130 may include or be formed of an organic dielectric material or a silicon-based dielectric material. The first bonding pads 165 may be disposed on the top surface 110a of the first semiconductor substrate 110 and may be electrically connected to corresponding first through structures 150. Differently from those shown in FIGS. 1A and 1B, the first bonding pads 165 may be redistribution pads. For example, redistribution patterns (not shown) may further be correspondingly/respectively provided between the first bonding pads 165 and the first through structures 150, and may be correspondingly/respectively and electrically coupled through the redistribution patterns to the first through structures 150. In this case, at least one of the first bonding pads 165 may not be vertically aligned with the first through structure 150 electrically connected thereto. For example, one or more first bonding pads 165 may not vertically overlap any of the first through structures 150. The first bonding pads 165 may include or be formed of metal, such as copper or aluminum.

Differently from those shown in FIGS. 1A and 1B, the first integrated circuits 115, the first circuit layer 120, and the first chip pads 155 may be disposed on the top surface 110a of the first semiconductor substrate 110, and the first backside dielectric layer 130 and the first bonding pads 165 may be disposed on the bottom surface 110b of the first semiconductor substrate 110.

A ratio of a thickness T10 of the first semiconductor substrate 110 to the thickness T12 of the first circuit layer 120 may be defined as a first ratio. The first ratio may range from about 1.7 to about 7. Because the first ratio is equal to or greater than about 1.7, the first semiconductor substrate 110 may endure weight of the second semiconductor chips 200. Because the first ratio is equal to or less than about 7, the first thickness T1 may not excessively increase. For example, because the first ratio is equal to or less than about 7, it may be possible to satisfy a condition that the first thickness T1 is equal to or less than about 60 μm.

The thickness T10 of the first semiconductor substrate 110 may range from about 15 μm to about 50 μm. The thickness T10 of the first semiconductor substrate 110 may be an interval/distance between the top and bottom surfaces 110a and 110b of the first semiconductor substrate 110. The thickness T12 of the first circuit layer 120 may range from about 10 μm to about 15 μm. The thickness T12 of the first circuit layer 120 may correspond to an interval/distance between the bottom surface 110b of the first semiconductor substrate 110 and a top surface of the first chip pad 155.

When the first semiconductor chip 100 includes the first backside dielectric layer 130, the first thickness T1 may be an interval/distance between the bottom surface of the first circuit layer 120 and a top surface of the first backside dielectric layer 130. When the first semiconductor chip 100 does not include the first backside dielectric layer 130, the first thickness T1 may be an interval/distance between the bottom surface of the first circuit layer 120 and the top surface 110a of the first semiconductor substrate 110.

Referring to FIGS. 1A and 1C, each of the second semiconductor chips 200 may include a second semiconductor substrate 210, second integrated circuits 215, a second circuit layer 220, second chip pads 255, and second through structures 250. The second semiconductor substrate 210 may include or be formed of a semiconductor material, such as silicon, germanium, or silicon-germanium. The second semiconductor substrate 210 may have a crystalline structure. The second integrated circuits 215 may be provided on one surface of the second semiconductor substrate 210. The one surface may be a bottom surface 210b of the second semiconductor substrate 210. The second integrated circuits 215 may include, for example, transistors. The second integrated circuits 215 may be of a different type from the first integrated circuits 115. For example, the second integrated circuits 215 may include memory circuits.

The second circuit layer 220 may be provided on the bottom surface 210b of the second semiconductor substrate 210. The second circuit layer 220 may include a second dielectric layer 221 and second wiring structures 223. The second dielectric layer 221 may be provided on the bottom surface 210b of the second semiconductor substrate 210 and may cover the second integrated circuits 215. The second dielectric layer 221 may include or be formed of a silicon-based dielectric material. The second dielectric layer 221 may include or be formed of a plurality of stacked layers. When the second dielectric layer 221 includes a plurality of layers, the second circuit layer 220 may have a thickness T22 that corresponds to an interval/distance between a bottom surface of a lowermost layer of the second dielectric layer 221 and a top surface of an uppermost layer of the second dielectric layer 221.

The second wiring structures 223 may be provided in the second dielectric layer 221. The second wiring structures 223 may be electrically connected to the second integrated circuits 215. The second wiring structures 223 may include second line parts and second via parts. For example, the second line parts may be conductor patterns extending horizontally, and the second via parts may be through vias formed of conductor patterns extending vertically and some of the second via parts may electrically connect some of the second line parts disposed different vertical levels to each other. Some of the second via parts may electrically connect some of the second line parts to the integrated circuits 215 and/or to the second chip pads 255. Some of the second line parts may electrically connect some of the second via parts to each other.

The second chip pads 255 may be disposed on a bottom surface of the second circuit layer 220 and may be exposed on a bottom surface of the second semiconductor chip 200. The second chip pads 255 may be electrically isolated/separated from each other. The second chip pads 255 may be electrically connected through the second wiring structures 223 to the second integrated circuits 215. The second chip pads 255 may include or be formed of metal, such as aluminum.

The second through structures 250 may be provided in and may penetrate the second semiconductor substrate 210. Each of the second through structures 250 may further penetrate at least a portion of the second circuit layer 220. The second through structures 250 may be electrically connected through the second wiring structures 223 to the second chip pads 255 and/or the second integrated circuits 215. The second through structures 250 may include or be formed of a conductive material, such as copper, titanium, tungsten, or any alloy thereof.

The second semiconductor chip 200 may include a second backside dielectric layer 230 and second bonding pads 265. The second backside dielectric layer 230 may be disposed on a top surface 210a of the second semiconductor substrate 210. The second backside dielectric layer 230 may include or be formed of an organic dielectric material or a silicon-based dielectric material. The second bonding pads 265 may be disposed on the top surface 210a of the second semiconductor substrate 210 and may be electrically connected to corresponding second through structures 250 respectively. Differently from those shown in FIGS. 1A and 1C, the second bonding pads 265 may be redistribution pads. For example, one or more second bonding pads 265 may not vertically overlap the second through structures 250. For example, redistribution patterns (not shown) may further be provided between the second bonding pads 265 and the second through structures 250, and the second bonding pads 265 may be respectively/correspondingly and electrically coupled through the redistribution patterns to the second through structures 250. The second bonding pads 265 may include or be formed of metal, such as copper or aluminum.

The second semiconductor substrate 210 may have a thickness T20 less than the thickness T10 of the first semiconductor substrate 110. The thickness T20 of the second semiconductor substrate 210 may range from about 10 μm to about 50 μm.

The thickness T22 of the second circuit layer 220 may be about 80% to about 120% of the thickness T12 of the first circuit layer 120. The thickness T22 of the second circuit layer 220 may range from about 10 μm to about 15 μm. The thickness T22 of the second circuit layer 220 may correspond to an interval/distance between the second chip pad 255 and the bottom surface 210b of the second semiconductor substrate 210.

A ratio of the thickness T20 of the second semiconductor substrate 210 to the thickness T22 of the second circuit layer 220 may be defined as a second ratio. The second ratio may be less than the first ratio. For example, the second ratio may range from about 0.5 to about 1.5. When the second ratio is equal to or greater than the first ratio, the second thickness T2 may be excessively large (e.g., equal to or greater than about 50 μm). When the second ratio is greater than about 1.5, the chip stack package 10 may be difficult to become compact-sized. When the second ratio is less than 0.5, the second semiconductor chips 200 may be easily damaged or may be difficult to handle. According to some embodiments, because a condition is satisfied where the second ratio ranges from about 0.5 to about 1.5, the second semiconductor chips 200 may be prevented from being damaged, and the chip stack package 10 may become small in size.

When the second semiconductor chip 200 includes the second backside dielectric layer 230, the second thickness T2 may be an interval/distance between the bottom surface of the second circuit layer 220 and a top surface of the second backside dielectric layer 230. When the second semiconductor chip 200 does not include the second backside dielectric layer 230, the second thickness T2 may be an interval/distance between the bottom surface of the second circuit layer 220 and the top surface 210a of the second semiconductor substrate 210.

Differently from those shown in FIGS. 1A and 1C, the second integrated circuits 215, the second circuit layer 220, and the second chip pads 255 may be disposed on the top surface 210a of the second semiconductor substrate 210, and the second backside dielectric layer 230 and the second bonding pads 265 may be disposed on the bottom surface 210b of the second semiconductor substrate 210.

Referring to FIGS. 1A and 1D, the third semiconductor chip 300 may include a third semiconductor substrate 310, third integrated circuits 315, a third circuit layer 320, and third chip pads 355. The third semiconductor chip 300 may include no through structure, e.g., formed through the third semiconductor substrate 310. For example, the third semiconductor chip 300 may not include a conductor through via vertically penetrating the third semiconductor substrate 310. The third semiconductor substrate 310 may include or be formed of, for example, silicon, germanium, or silicon-germanium. The third integrated circuits 315 may be provided on a bottom surface 310b of the third semiconductor substrate 310. The third integrated circuits 315 may include, for example, transistors. The third integrated circuits 315 may be of a different type from the first integrated circuits 115 and may be of the same type as the second integrated circuits 215. For example, the third integrated circuits 315 may include memory circuits.

The third circuit layer 320 may be provided on the bottom surface 310b of the third semiconductor substrate 310. The third circuit layer 320 may include a third dielectric layer 321 and third wiring structures 323. The third dielectric layer 321 may be provided on the bottom surface 310b of the third semiconductor substrate 310 and may cover the third integrated circuits 315. The third dielectric layer 321 may include or be formed of a silicon-based dielectric material. The third dielectric layer 321 may include or be formed of a plurality of stacked layers. When the third dielectric layer 321 includes a plurality of layers, the third circuit layer 320 may have a thickness T32 that corresponds to an interval/distance between a bottom surface of a lowermost layer of the third dielectric layer 321 and a top surface of an uppermost layer of the third dielectric layer 321.

The third wiring structures 323 may be provided in the third dielectric layer 321. The third wiring structures 323 may be electrically connected to the third integrated circuits 315. The third wiring structures 323 may include third line parts and third via parts. For example, the third line parts may be conductor patterns extending horizontally, and the third via parts may be through vias formed of conductor patterns extending vertically and some of the third via parts may electrically connect some of the third line parts disposed different vertical levels to each other. Some of the third via parts may electrically connect some of the third line parts to the integrated circuits 315 and/or to the third chip pads 355. Some of the third line parts may electrically connect some of the third via parts to each other.

The third chip pads 355 may be disposed on a bottom surface of the third circuit layer 320 and may be exposed on a bottom surface of the third semiconductor chip 300. The third chip pads 355 may be electrically connected through the third wiring structures 323 to the third integrated circuits 315. The third chip pads 355 may include or be formed of metal, such as aluminum.

No bonding pad may be separately provided on a top surface of the third semiconductor chip 300.

As the third semiconductor chip 300 includes no through structure, it may be possible to omit a thinning process for the third semiconductor substrate 310. The third semiconductor chip 300 may be manufactured in a simplified process. The third semiconductor substrate 310 may have a thickness T30 greater than the thickness T10 of the first semiconductor substrate 110. The thickness T32 of the third circuit layer 320 may be about 80% to about 120% of the thickness T12 of the first circuit layer 120. The thickness T32 of the third circuit layer 320 may range, for example, from about 10 μm to about 15 μm. The thickness T32 of the third circuit layer 320 may be about 80% to about 120% of the thickness T22 of the second circuit layer 220. The thickness T32 of the third circuit layer 320 may correspond to an interval/distance between the bottom surface 310b of the third semiconductor substrate 310 and a top surface of the third chip pad 355.

A ratio of the thickness T30 of the third semiconductor substrate 310 to the thickness T32 of the third circuit layer 320 may be defined as a third ratio. The third ratio may be greater than the second ratio.

Referring back to FIG. 1A, the solder terminal 500 may be provided on the bottom surface of the first semiconductor chip 100. An external electrical signal may be transmitted through the solder terminal 500 to the first semiconductor chip 100. The solder terminal 500 may be a solder ball. Alternatively, the solder terminal 500 may be a conductive pillar. The solder terminal 500 may include or be formed of metal, such as a solder material. The solder material may include tin (Sn), silver (Ag), zinc (Zn), or any alloy thereof. The chip stack package 10 may include a plurality of solder terminals 500, and the plurality of solder terminals 500 may be laterally spaced apart from each other.

First bump patterns 510 may be interposed between the first semiconductor chip 100 and a lowermost second semiconductor chip 200. The first bump patterns 510 may be laterally spaced apart and electrically isolated/separated from each other. As shown in FIG. 1A, the first bump patterns 510 may be correspondingly/respectively disposed between and electrically coupled to the first bonding pads 165 and the second chip pads 255. Each of the first bump patterns 510 may be a solder ball or a pillar. The first bump patterns 510 may include or be formed of metal or a solder material. The first bump patterns 510 may be electrically connected through the first through structures 150 to the first integrated circuits 115 and/or the solder terminals 500.

Second bump patterns 520 may be interposed between the second semiconductor chips 200. For example, the second semiconductor chips 200 may be vertically stacked together. For example, one second semiconductor chip 200 may be disposed on another second semiconductor chip 200. As shown in FIG. 1C, the second bump patterns 520 may be correspondingly/respectively coupled to the second bonding pads 265 of the second semiconductor chips 200 and to the second chip pads 255 of the second semiconductor chips 200. Each of the second bump patterns 520 may be a solder ball or a pillar. The second bump patterns 520 may include or be formed of metal or a solder material. The second semiconductor chips 200 may be electrically connected to the first semiconductor chip 100 and the solder terminals 500 through the second bump patterns 520, the first bump patterns 510, and the first through structures 150.

Third bump patterns 530 may be interposed between the third semiconductor chip 300 and an uppermost second semiconductor chip 200. As shown in FIGS. 1A and 1D, the third bump patterns 530 may be correspondingly/respectively and electrically coupled to the third chip pads 355 and the second bonding pads 265 of the uppermost second semiconductor chip 200. For example, each of the third bump patterns 530 may contact and/or electrically connected to a corresponding second bonding pad 265 and a corresponding third chip pad 355. Each of the third bump patterns 530 may be a solder ball or a pillar. The third bump patterns 530 may include or be formed of metal or a solder material. The third semiconductor chip 300 may be electrically connected to the first semiconductor chip 100 and the solder terminals 500 through the third bump patterns 530, the second bump patterns 520, the second through structures 250, the first bump patterns 510, and the first through structures 150.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

A first under-fill layer 410 may be provided in a first gap between the first semiconductor chip 100 and the lowermost second semiconductor chip 200, thereby encapsulating/surrounding the first bump patterns 510. Second under-fill layers 420 may be correspondingly provided in second gaps between the second semiconductor chips 200, thereby encapsulating/surrounding the second bump patterns 520. A third under-fill layer 430 may be provided in a third gap between the uppermost second semiconductor chip 200 and the third semiconductor chip 300, thereby encapsulating/surrounding the third bump patterns 530. The first, second, and third under-fill layers 410, 420, and 430 may include or be formed of a dielectric polymer, such as an epoxy-based polymer. Alternatively, the first, second, and third under-fill layers 410, 420, and 430 may include or may be a non-conductive film (NCF).

The first semiconductor chip 100 may be provided on its top surface with a molding layer 400 that covers lateral surfaces of the second semiconductor chips 200 and a lateral surface of the third semiconductor chip 300. For example, the molding layer 400 may surround and contact sidewalls of the second semiconductor chips 200 and the third semiconductor chip 300. The molding layer 400 may expose a top surface of the third semiconductor chip 300. For example, the molding layer 400 may have a top surface at substantially the same level as that of the top surface of the third semiconductor chip 300. For example, the top surface of the molding layer 400 and the top surface of the third semiconductor chip 300 may be coplanar. For another example, the molding layer 400 may further cover the top surface of the third semiconductor chip 300. The molding layer 400 may have sidewalls aligned with those of the first semiconductor chip 100. For example, the sidewalls of the molding layer 400 and the sidewalls of the first semiconductor chip 100 may be coplanar. The molding layer 400 may include or be formed of a dielectric polymer, such as an epoxy-based polymer. The molding layer 400 may include or be formed of a different material from that of the first, second, and third under-fill layers 410, 420, and 430.

Differently from those shown in FIGS. 1A-1D, the first, second, and third under-fill layers 410, 420, and 430 may be omitted, and the molding layer 400 may further extend into gaps between the first, second, and third semiconductor chips 100, 200, and 300. For example, the molding layer 400 may further extend into at least one selected from the first gap, the second gaps, and the third gap. In this case, the molding layer 400 may encapsulate/surround and contact the first bump patterns 510, the second bump patterns 520, and the third bump patterns 530.

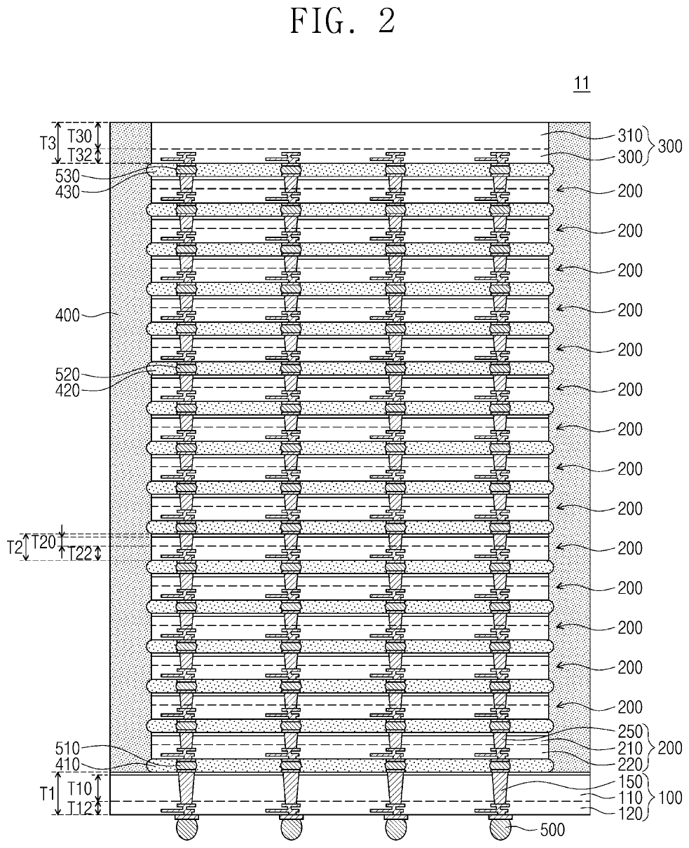

FIG. 2 illustrates a cross-sectional view showing a semiconductor package according to some example embodiments. The embodiments illustrated in FIG. 2 include same elements/components as embodiments described above, and duplicate descriptions may be omitted in the below descriptions for brevity.

Referring to FIG. 2, a semiconductor package may be a chip stack package 11. The chip stack package 11 may include a first semiconductor chip 100, second semiconductor chips 200, a third semiconductor chip 300, solder terminals 500, and a molding layer 400. The first semiconductor chip 100, the second semiconductor chips 200, the third semiconductor chip 300, the solder terminals 500, and the molding layer 400 may be substantially the same as those discussed above with reference to FIGS. 1A to 1D. In contrast, a sum of the numbers of the second and third semiconductor chips 200 and 300 may be 16. The number of the second semiconductor chips 200 may be expressed by 4n−1, wherein n is four.

The chip stack package 11 may further include at least one selected from first bump patterns 510, second bump patterns 520, third bump patterns 530, a first under-fill layer 410, a second under-fill layer 420, and a third under-fill layer 430.

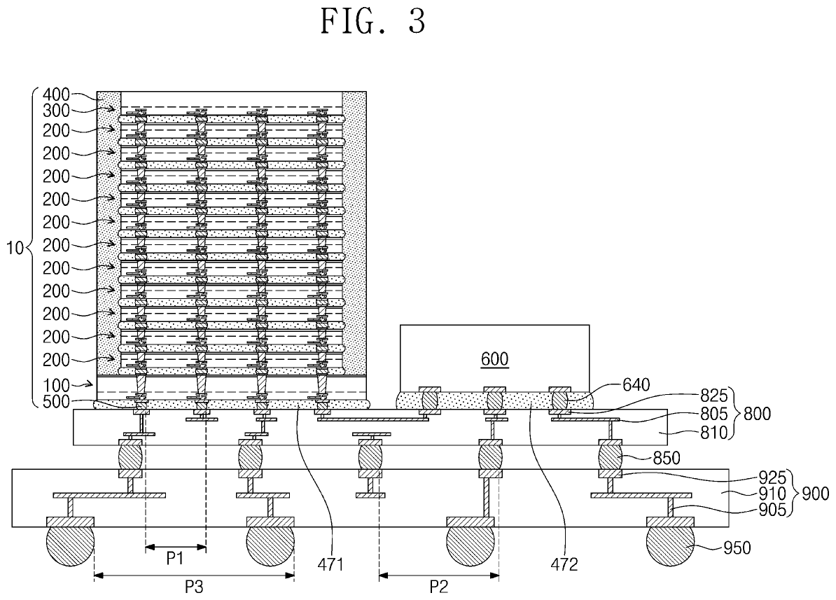

FIG. 3 illustrates a cross-sectional view showing a semiconductor package according to some example embodiments.

Referring to FIG. 3, a semiconductor package may include external terminals 950, a package substrate 900, an interposer substrate 800, interposer bumps 850, a chip stack package 10, and a semiconductor device 600.

The package substrate 900 may be a printed circuit board (PCB) having a circuit pattern. The package substrate 900 may include a dielectric base layer 910, substrate pads 925, and internal lines 905. The dielectric base layer 910 may include a plurality of stacked layers. Alternatively, the dielectric base layer 910 may be a single layer. The substrate pads 925 may be exposed on a top surface of the package substrate 900. The internal lines 905 may be disposed in the dielectric base layer 910 and may be electrically coupled to corresponding substrate pads 925. The internal lines 905 may include horizontally extending conductive line patterns and vertically extending via patterns. The phrase “electrically coupled to the package substrate 900” may mean “electrically coupled to at least one of the internal lines 905 of the package substrate 900.” The substrate pads 925 and the internal lines 905 may include or be formed of metal, such as one or more of copper, aluminum, tungsten, and titanium.

The external terminals 950 may be disposed on a bottom surface of the package substrate 900. External electrical signals may be transmitted through the external terminals 950 to the package substrate 900. The external terminals 950 may be solder balls, pillars, bumps, or combinations thereof. The external terminals 950 may include or be formed of metal, such as a solder material.

The interposer substrate 800 may be disposed on the package substrate 900. The interposer substrate 800 may include a base layer 810, conductive pads 825, and conductive lines 805. The base layer 810 may include or be formed of a dielectric material. The base layer 810 may include or be formed of a plurality of layers. The conductive pads 825 may be exposed on a top surface of the interposer substrate 800. The conductive lines 805 may be provided in the base layer 810 of the interposer substrate 800 and may be electrically coupled to corresponding conductive pads 825. The conductive lines 805 may include horizontally extending conductive patterns and vertically extending conductive vias. In this description, the phrase “electrically connected/coupled to the interposer substrate 800” may mean “electrically connected/coupled to at least one of the conductive lines 805 of the interposer substrate 800.” The conductive pads 825 and the conductive lines 805 may include or be formed of metal, such as one or more of copper, aluminum, tungsten, and titanium.

The interposer bumps 850 may be interposed between and electrically coupled to the package substrate 900 and the interposer substrate 800. For example, the interposer bumps 850 may be disposed on and electrically coupled to corresponding substrate pads 925. For example, the interpose bumps 850 may contact respective substrate pads 925. Each of the interposer bumps 850 may be a solder ball, a bump, or a pillar. The interposer bumps 850 may include or be formed of metal, such as a solder material. The interposer bumps 850 may have a pitch P2 less than a pitch P3 of the external terminals 950. For example, the interposer bumps 850 may be interposer terminals or solder terminals.

The chip stack package 10 may be disposed on the top surface of the interposer substrate 800. As discussed above, the chip stack package 10 may include solder terminals 500, a first semiconductor chip 100, second semiconductor chips 200, and a third semiconductor chip 300. The chip stack package 10 may further include a molding layer 400. For example, the chip stack package 10 discussed with respect to the example of FIGS. 1A to 1D may be mounted on the top surface of the interposer substrate 800. Alternatively, the chip stack package 11 of FIG. 2 may be mounted on the top surface of the interposer substrate 800. Dissimilarly, the number of the second semiconductor chips 200 may be expressed by 4n−1, wherein n is a natural number equal to or greater than five. Solder terminals 500 may be electrically coupled to corresponding conductive pads 825, and the chip stack package 10 may be electrically connected to the interposer substrate 800. The solder terminals 500 may have a pitch P1 less than the pitch P2 of the interposer bumps 850. The pitch P1 of the solder terminals 500 may be less than the pitch P3 of the external terminals 950.

The semiconductor device 600 may be mounted on the top surface of the interposer substrate 800. The semiconductor device 600 may be laterally spaced apart from the chip stack package 10. Fourth bump patterns 640 may be interposed between and electrically coupled to the interposer substrate 800 and the semiconductor device 600. For example, the semiconductor device 600 may be electrically coupled through one or more metal lines (e.g., the conductive lines 805) to the chip stack package 10 or the package substrate 900.

The semiconductor device 600 may be a fourth semiconductor chip. The fourth semiconductor chip may be a logic chip. The fourth semiconductor chip may be of a different type from the first semiconductor chip 100. For example, the fourth semiconductor chip may have a different function from that of the first semiconductor chip 100. The semiconductor device 600 may be, for example, an application specific integrated circuit (ASIC) chip or an application processor (AP) chip. The ASIC chip may include an application specific integrated circuit (ASIC). Alternatively, the semiconductor device 600 may include or may be a central processing unit (CPU) or a graphic processing unit (GPU). The first semiconductor chip 100 and the semiconductor device 600 may be electrically connected to each other through the conductive lines 805 of the interposer substrate 800.

The semiconductor package may further include at least one selected from a first under-fill pattern 471 and a second under-fill pattern 472. The first under-fill pattern 471 may be interposed between the interposer substrate 800 and the chip stack package 10, thereby encapsulating/surrounding the solder terminals 500. The second under-fill pattern 472 may be interposed between the interposer substrate 800 and the semiconductor device 600, thereby encapsulating/surrounding the fourth bump patterns 640. The first and second under-fill patterns 471 and 472 may include or be formed of a dielectric polymer.

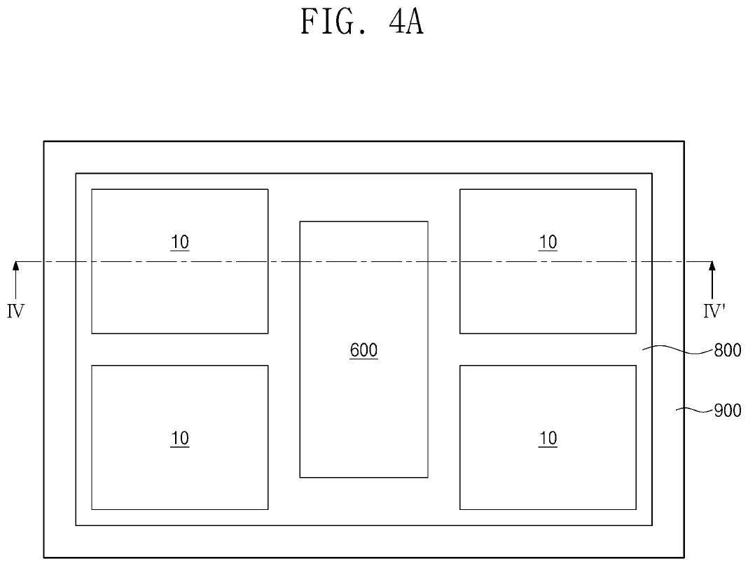

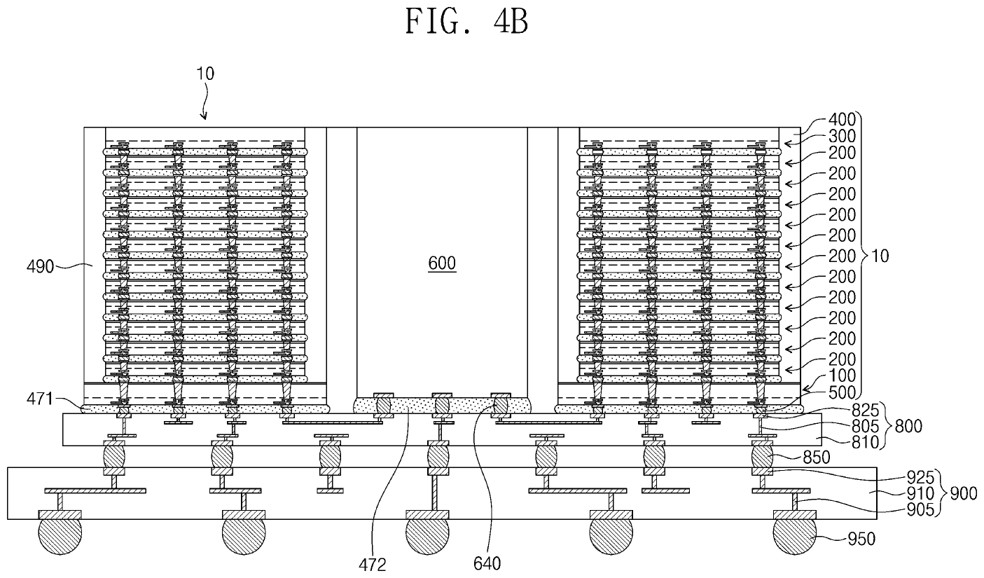

FIG. 4A illustrates a plan view showing a semiconductor package according to some example embodiments. FIG. 4B illustrates a cross-sectional view taken along line IV-IV′ of FIG. 4A.

Referring to FIGS. 4A and 4B, a semiconductor package may include external terminals 950, a package substrate 900, an interposer substrate 800, a plurality of chip stack packages 10, and a semiconductor device 600.

The plurality of chip stack packages 10 may be mounted on a top surface of the interposer substrate 800. The chip stack packages 10 may be laterally spaced apart from each other. For example, each of the chip stack packages 10 may be substantially the same as that discussed with respect to the example of FIGS. 1A to 1D. Differently from those shown in FIG. 4B, at least one of the chip stack packages 10 may include second semiconductor chips 200 whose number is expressed by 4n−1, wherein n is a natural number equal to or greater than four.

The semiconductor device 600 may be disposed between the chip stack packages 10. The semiconductor device 600 may be laterally spaced apart from the chip stack packages 10. Each of the chip stack packages 10 may be electrically connected through the interposer substrate 800 to the semiconductor device 600.

The semiconductor package may further include a molding pattern 490. The molding pattern 490 may be disposed on the top surface of the interposer substrate 800, and may cover sidewalls of the chip stack packages 10 and sidewalls of the semiconductor device 600.

Differently from that shown in FIG. 4B, the number of the chip stack packages 10 may be variously changed. For example, the semiconductor package may include two chip stack packages 10, six chip stack packages 10, or eight chip stack packages 10, but the present inventive concepts are not limited thereto.

According to the present inventive concepts, a semiconductor package may include a plurality of upper semiconductor chips (e.g., second and third semiconductor chips) that are vertically stacked on a lower semiconductor chip (e.g., a first semiconductor chip). The number of the upper semiconductor chips may be expressed by 4n, wherein n is a natural number equal to or greater than three. Accordingly, the semiconductor package may have high-capacity characteristics.

The upper semiconductor chips may each have a thickness that is about 0.4 to about 0.95 times that of the lower semiconductor chip. Accordingly, the upper semiconductor chips may be easy to handle, and a chip stack package may become small in size.

This detailed description of the present inventive concepts should not be construed as limited to the embodiments set forth herein, and it is intended that the present inventive concepts cover the various combinations, the modifications and variations of this invention without departing from the spirit and scope of the present inventive concepts.

1. A semiconductor package, comprising:
a lower semiconductor chip; and
a plurality of upper semiconductor chips that are vertically stacked on a top surface of the lower semiconductor chip,
wherein the upper semiconductor chips include a plurality of first upper semiconductor chips and a second upper semiconductor chip, the first upper semiconductor chips being between the lower semiconductor chip and the second upper semiconductor chip,
wherein a thickness of each of the first upper semiconductor chips is about 0.4 times to about 0.95 times a thickness of the lower semiconductor chip,
wherein a thickness of the second upper semiconductor chip is the same as or greater than the thickness of each of the first upper semiconductor chips, and
wherein a total number of the first upper semiconductor chips and the second upper semiconductor chip is 4n, wherein n is a natural number equal to or greater than three.

2. The semiconductor package of claim 1, wherein
the thickness of the lower semiconductor chip is in a range of about 30 μm to about 60 μm, and
the thickness of each of the first upper semiconductor chips is in a range of about 25 μm to about 50 μm.

3. The semiconductor package of claim 1, wherein the second upper semiconductor chip does not include a through structure.

4. The semiconductor package of claim 3, wherein
the lower semiconductor chip includes a first semiconductor substrate, a first circuit layer, and a first through structure,
each of the first upper semiconductor chips includes a second semiconductor substrate, a second circuit layer, and a second through structure, and
a second ratio of a thickness of the second semiconductor substrate to a thickness of the second circuit layer is less than a first ratio of a thickness of the first semiconductor substrate to a thickness of the first circuit layer.

5. The semiconductor package of claim 4, wherein
the thickness of the second circuit layer is about 80% to about 120% of the thickness of the first circuit layer, and
the thickness of the second semiconductor substrate is less than the thickness of the first semiconductor substrate.

6. The semiconductor package of claim 1, wherein
the lower semiconductor chip is a logic chip, and
the first upper semiconductor chips and the second upper semiconductor chip are memory chips.

7. The semiconductor package of claim 1, further comprising a molding layer on the top surface of the lower semiconductor chip, the molding layer covering sidewalls of the first upper semiconductor chips and a sidewall of the second upper semiconductor chip,
wherein the molding layer exposes a top surface of the second upper semiconductor chip.

8. The semiconductor package of claim 1, further comprising:
an interposer substrate;
a semiconductor device mounted on a top surface of the interposer substrate; and
a plurality of interposer terminals on a bottom surface of the interposer substrate,
wherein the first upper semiconductor chips are on the top surface of the interposer substrate and are laterally spaced apart from the semiconductor device.

9. A semiconductor package, comprising:
a first semiconductor chip that includes a first semiconductor substrate, a first circuit layer, and a first through structure; and
a plurality of second semiconductor chips that are vertically stacked on a top surface of the first semiconductor chip,
wherein each of the second semiconductor chips includes a second semiconductor substrate, a second circuit layer, and a second through structure,
wherein a thickness of each of the second semiconductor chips is about 0.4 times to about 0.95 times a thickness of the first semiconductor chip, and
wherein a second ratio of a thickness of the second semiconductor substrate to a thickness of the second circuit layer is less than a first ratio of a thickness of the first semiconductor substrate to a thickness of the first circuit layer.

10. The semiconductor package of claim 9, wherein the thickness of the second semiconductor substrate is less than the thickness of the first semiconductor substrate.

11. The semiconductor package of claim 10, wherein the thickness of the second circuit layer is about 80% to about 120% of the thickness of the first circuit layer.

12. The semiconductor package of claim 9, further comprising a third semiconductor chip that includes a third semiconductor substrate and a third circuit layer,
wherein the third semiconductor chip does not include a through structure,
wherein the second semiconductor chips are between the first semiconductor chip and the third semiconductor chip, and
wherein the thickness of the second semiconductor substrate is less than a thickness of the third semiconductor substrate.

13. The semiconductor package of claim 12, wherein a third ratio of the thickness of the third semiconductor substrate to a thickness of the third circuit layer is greater than the second ratio.

14. The semiconductor package of claim 9, wherein
the first ratio is in a range of about 1.7 to about 7, and
the second ratio is in a range of about 0.5 to about 1.5.

15. The semiconductor package of claim 9, wherein the number of the second semiconductor chips is 4n−1, wherein n is a natural number equal to or greater than three.

16. The semiconductor package of claim 9, wherein a width of the first semiconductor chip is greater than widths of the second semiconductor chips.

17. A semiconductor package, comprising:
a first semiconductor chip;
a plurality of solder terminals on a bottom surface of the first semiconductor chip;
a plurality of second semiconductor chips that are vertically stacked on a top surface of the first semiconductor chip;
a third semiconductor chip on the second semiconductor chips; and
a molding layer on the top surface of the first semiconductor chip, the molding layer covering sidewalls of the second semiconductor chips and a sidewall of the third semiconductor chip,
wherein the first semiconductor chip includes:
a first semiconductor substrate;
a plurality of first integrated circuits on one surface of the first semiconductor substrate;
a first circuit layer on the one surface of the first semiconductor substrate, the first circuit layer including a first dielectric layer and a first wiring structure; and
a first through structure formed in the first semiconductor substrate and electrically connected to the first integrated circuits,
wherein each of the second semiconductor chips includes:
a second semiconductor substrate;
a plurality of second integrated circuits on one surface of the second semiconductor substrate;
a second circuit layer on the one surface of the second semiconductor substrate, the second circuit layer including a second dielectric layer and a second wiring structure; and
a second through structure formed in the second semiconductor substrate and electrically connected to the second integrated circuits,
wherein the third semiconductor chip includes:
a third semiconductor substrate;
a plurality of third integrated circuits on one surface of the third semiconductor substrate; and
a third circuit layer on the one surface of the third semiconductor substrate, the third circuit layer including a third dielectric layer and a third wiring structure,
wherein the third semiconductor chip does not include a through structure,
wherein a ratio of a thickness of the first semiconductor substrate to a thickness of the first circuit layer is in a range of about 1.7 to about 7,
wherein a ratio of a thickness of the second semiconductor substrate to a thickness of the second circuit layer is in a range of about 0.5 to about 1.5,
wherein a thickness of each of the second semiconductor chips is about 0.4 times to about 0.95 times a thickness of the first semiconductor chip,
wherein a thickness of the third semiconductor chip is greater than the thickness of each of the second semiconductor chips, and
wherein a total number of the second semiconductor chips and the third semiconductor chip is 4n, wherein n is a natural number equal to or greater than three.

18. The semiconductor package of claim 17, wherein a ratio of a thickness of the third semiconductor substrate to a thickness of the third circuit layer is greater than the ratio of the thickness of the second semiconductor substrate to the thickness of the second circuit layer.

19. The semiconductor package of claim 17, wherein
the thickness of the second circuit layer is about 80% to about 120% of the thickness of the first circuit layer,
the thickness of the third circuit layer is about 80% to about 120% of the thickness of the first circuit layer, and
the thickness of the second semiconductor substrate is less than the thickness of the first semiconductor substrate and a thickness of the third semiconductor substrate.

20. The semiconductor package of claim 17, wherein
the thickness of the first semiconductor chip is in a range of about 30 μm to about 60 μm,
the thickness of each of the second semiconductor chips is in a range of about 25 μm to about 50 μm, and
an interval between the bottom surface of the first semiconductor chip and a top surface of the third semiconductor chip is in a range of about 500 μm to about 1,000 μm.
